(19) United States
(12) Patent Application Publication
(10) Pub. No.: US 2014/0029339 A1
(43) Pub. Date: Jan. 30, 2014

(54) NONVOLATILE SEMICONDUCTOR MEMORY DEVICE AND METHOD FOR ITS USE

(71) Applicant: KABUSHIKI KAISHA TOSHIBA, Tokyo (JP)

(72) Inventors: Wataru SAKAMOTO, Mie (JP); Hideto TAKEKIDA, Aichi (JP)

(73) Assignee: KABUSHIKI KAISHA TOSHIBA, Tokyo (JP)

(21) Appl. No.: 13/951,649

(22) Filed: Jul. 26, 2013

(30) Foreign Application Priority Data
Jul. 27, 2012 (JP) 2012-167145

(51) Int. Cl. G11C 16/04; H01L 27/04

(52) U.S. Cl. CPC G11C 16/0483; H01L 27/04
USPC 365/185.05; 257/368

(57) ABSTRACT

A nonvolatile semiconductor memory device comprises multiple cell units that are arranged in the form of a matrix in the memory cell region, a bit line that is connected to the drain of one side of the selector gate transistor of each of the cell units and that is arranged in an extending direction of the multiple cell units, a source line that is connected to the source of the other side of the selector gate transistor of each of the cell units and that is arranged at right angle to the multiple cell units, and a bit line charge-discharge transistor that charges and discharges the bit line and that is arranged adjacent to the contact connected to the bit line on the region of drain side of at least one of the selector gate transistors of the multiple cell units.

### CROSS-REFERENCE TO RELATED APPLICATION

This application is based upon and claims the benefit of priority from Japanese Patent Application No. 2012-167145, filed Jul. 27, 2012, the entire contents of which are incorporated herein by reference.

### FIELD

Embodiments described herein generally relate to nonvolatile semiconductor memory devices and a method for their use.

### BACKGROUND

In the case of a NAND flash memory device, as an example of a nonvolatile semiconductor memory device, as the device (memory cell) size is reduced to accommodate a larger memory capacity, the wiring resistance and wiring capacity tend to increase as the memory cells become closer together and as the distances between the word line and bit line as well as between bit lines become smaller. The larger the wiring resistance and wiring capacity of the bit lines, the more time it takes to charge and discharge the memory cells. An increase in the charging and discharging time results in a decrease in the operation speed of the memory device, so the device may not satisfy an operation speed specification.

Given this problem, the following solution has been suggested. By dividing the bit lines connected to the sense amplifier, a switch is created wherein either a long operating time configuration or short operation time configuration can be selected, depending on the use. In this way, the readout time from the memory cell arranged on the bit line near the sense amplifier can be shortened.

However, the problem remains when selecting the other option of the switch system wherein the bit line is connected because the readout time cannot be shortened.

### DESCRIPTION OF THE DRAWINGS

FIG. 1 is one example of an outline of the electrical system which is a part of the memory cell region and the peripheral circuit region of the NAND flash memory device employed in a first embodiment.

FIG. 2 is one example of an outline figure of the electrical system of the memory cell region.

FIG. 3A is one example of a two-dimensional diagram of the division configuration of the memory cell region and FIG. 3B is a diagram of the electrical system of the division configuration of the memory cell region.

FIG. 4 is one example of a diagram of a cross section of the division configuration of the memory cell region.

FIGS. 5A and 5B are one example of operation figures of the electrical system when the division transistor having the configuration of FIG. 3A and FIG. 3B is turned off.

FIGS. 6A to 6C are one example of function figures of the operations and charge/discharge conditions of the bit line divider transistors and the bit line charge-discharge transistors.

FIG. 7A is one example of a schematic top-or plan view drawing and FIG. 7B is one example of a schematic diagram of a cross section along the B-B line in FIG. 7A at a certain point in the production step (#1).

FIG. 8A is one example of a schematic top-view drawing and FIG. 8B is one example of a schematic diagram of a cross section along the B-B line in FIG. 8A at a certain point in the production step (#2).

FIG. 9A is one example of a schematic top-view drawing and FIG. 9B is one example of a schematic diagram of a cross section along the B-B line in FIG. 9A at a certain point in the production step (#3).

FIG. 10A is one example of a schematic top-view drawing and FIG. 10B is one example of a schematic diagram of a cross section along the B-B line in FIG. 10A at a certain point in the production step (#4).

FIG. 11A is one example of a schematic top-view drawing and FIG. 11B is one example of a schematic diagram of a cross section along the B-B line in FIG. 11A at a certain point in the production step (#5).

FIG. 12A is one example of a schematic top-view drawing and FIG. 12B is one example of a schematic diagram of a cross section along the B-B line in FIG. 12A at a certain point in the production step (#6).

FIG. 13A is one example of a schematic top-view drawing, FIG. 13B is one example of a schematic diagram of a cross section along the B-B line in FIG. 13A, and FIG. 13C is one example of a schematic diagram of a cross section along the C-C line in FIG. 13A at a certain point in the production step (#7).

FIG. 14A is one example of a schematic top-view drawing, FIG. 14B is one example of a schematic diagram of a cross section along the B-B line in FIG. 14A, and FIG. 14C is one example of a schematic diagram of a cross section along the C-C line in FIG. 14A at a certain point in the production step (#8).

FIG. 15A is one example of a schematic top-view drawing, FIG. 15B is one example of a schematic diagram of a cross section along the B-B line in FIG. 15A, and FIG. 15C is one example of a schematic diagram of a cross section along the C-C line in FIG. 15A at a certain point in the production step (#9).

FIG. 16A is one example of a schematic top-view drawing, FIG. 16B is one example of a schematic diagram of a cross section along the B-B line in FIG. 16A, and FIG. 16C is one example of a schematic diagram of a cross section along the C-C line in FIG. 16A at a certain point in the production step (#10).

FIG. 17A is one example of a schematic top-view drawing, FIG. 17B is one example of a schematic diagram of a cross section along the B-B line in FIG. 17A, and, FIG. 17C is one example of a schematic diagram of a cross section along the C-C line in FIG. 17A at a certain point in the production step (#11).

FIG. 18A is one example of a schematic top-view drawing, FIG. 18B is one example of a schematic diagram of a cross section along the B-B line in FIG. 18A, and FIG. 18C is one example of a schematic diagram of a cross section along the C-C line in FIG. 18A at a certain point in the production step (#12).

FIG. 19A is one example of a schematic top-view drawing, FIG. 19B is one example of a schematic diagram of a cross section along the B-B line in FIG. 19A, and FIG. 19C is one example of a schematic diagram of a cross section along the C-C line in FIG. 19A at a certain point in the production step (#13).

FIG. 20A is one example of a schematic top-view drawing, FIG. 20B is one example of a schematic diagram of a cross section along the B-B line in FIG. 20A, and FIG. 20C is one example of a schematic diagram of a cross section along the C-C line in FIG. 20A at a certain point in the production step (#14).

FIG. 21A is one example of a schematic top-view drawing, FIG. 21B is one example of a schematic diagram of a cross section along the B-B line in FIG. 21A, and FIG. 21C is one example of a schematic diagram of a cross section along the C-C line in FIG. 21A at a certain point in the production step (#15).

FIG. 22A is one example of a schematic top-view drawing, FIG. 22B is one example of a schematic diagram of a cross section along the B-B line in FIG. 22A, and FIG. 22C is one example of a schematic diagram of a cross section along the C-C line in FIG. 22A at a certain point in the production step (#16).

FIG. 23A is one example of a schematic top-view drawing, FIG. 23B is one example of a schematic diagram of a cross section along the B-B line in FIG. 23A, and FIG. 23C is one example of a schematic diagram of a cross section along the C-C line in FIG. 23A at a certain point in the production step (#17).

FIG. 24 is one example of a schematic diagram of a cross section of the division configuration of the memory cell region showing a second embodiment.

FIG. 25A is one example of a two-dimensional diagram of the division configuration of the memory cell region and FIG. 25B is a diagram of the electrical system of the division configuration of the memory cell region, both of which show the second embodiment.

FIG. 26A is one example of a two-dimensional diagram of the division configuration of the memory cell region and FIG. 26B is a diagram of the electrical system of the division configuration of the memory cell region, both of which showing a third embodiment.

FIG. 27A is one example of a two-dimensional diagram of the division configuration of the memory cell region and FIG. 27B is a diagram of the electrical system of the division configuration of the memory cell region, both of which show a fourth embodiment.

### DETAILED DESCRIPTION

A nonvolatile semiconductor memory device according to an embodiment comprises multiple memory cell transistors that are arranged in the form of a matrix in a memory cell region and that are connected in series, multiple cell units including selector gate transistors that are connected to either side of the multiple memory cell transistors, bit lines that are arranged in an extending direction of the multiple cell units and that are connected to one side of the drain of the selector gate transistor of each cell unit, source lines that are arranged at a right angle (orthogonal) to the multiple cell units and that are connected to the source on the other side of the selector gate transistor of each cell unit, and a bit line charge-discharge transistor that charges and discharges the bit line and that is arranged adjacent to the contact that is connected to the bit line in at least one of the drain sides of the region of one side of the selector gate transistor of the multiple cell units.

### First Embodiment

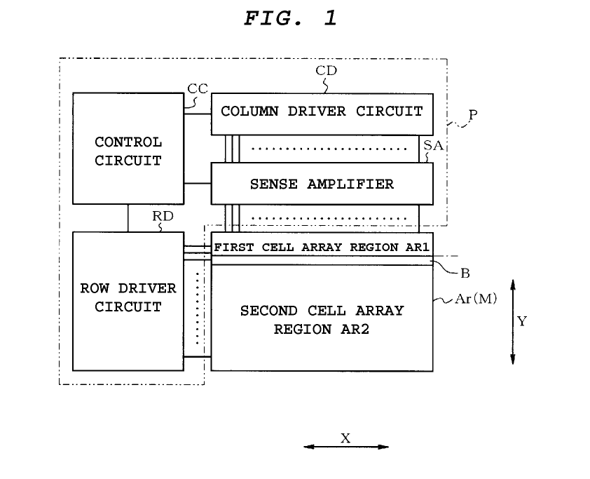

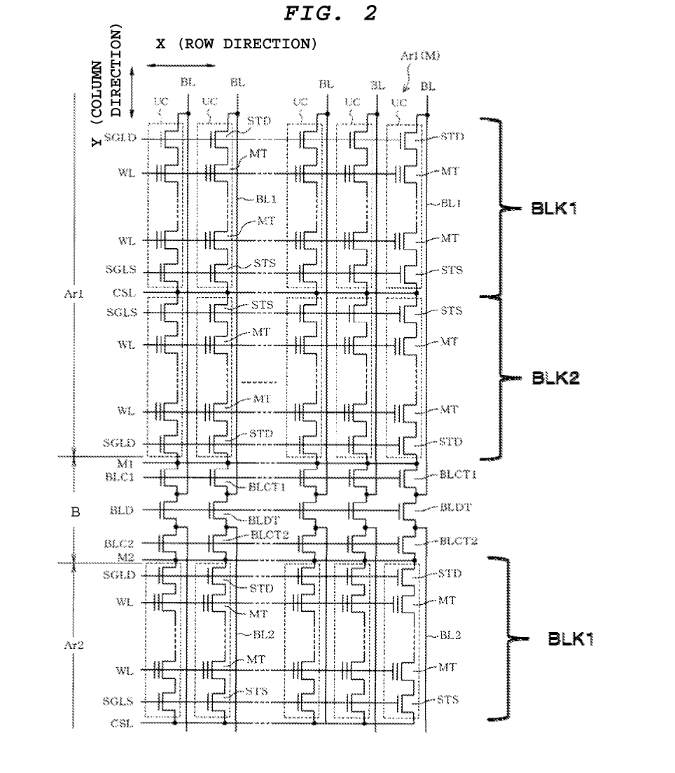

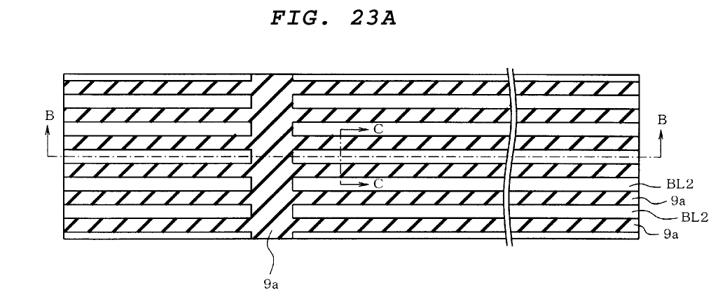

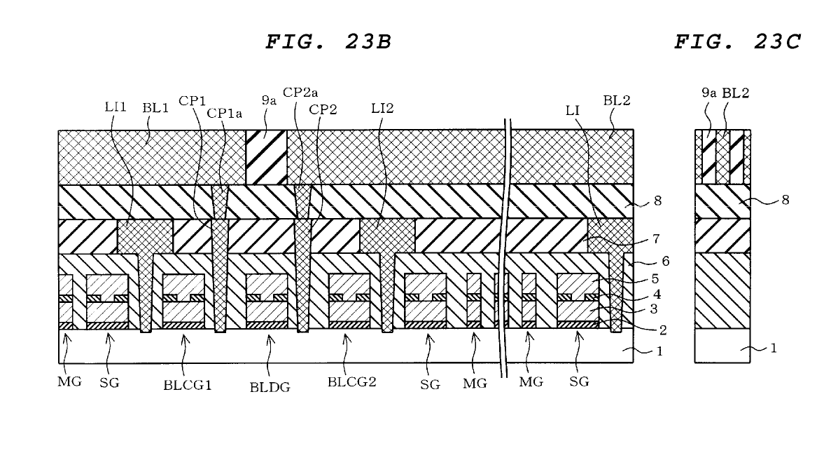

The first embodiment hereof as applied to a NAND flash memory device is explained below, in conjunction with FIG. 1 and FIGS. 23A and 23B. The drawings are schematic, so the relationship between the thickness and the dimensions, or the ratio or relative sizes of the thickness of each layer may not be proportionate to the actual size. Additionally, the directions showing the top, bottom, left, and right are relative positions with the circuit formation side of the semiconductor substrate facing upward and may not necessarily correspond to directions referencing the gravitational acceleration direction.

FIG. 1 is a one example of schematic block diagram of the electrical system of the NAND flash memory device, wherein the flash memory device comprises the memory cell region M and peripheral circuit region P. The memory cell region M comprises the memory cell array Ar including multiple memory cells arranged in the form of a matrix. The memory cell array Ar is divided into 3 regions in the Y direction: the first cell array region Ar1, boundary region B, and the second cell array region Ar2.

The first cell array region Ar1 can operate at a faster rate than the second cell array region Ar2. For example, the first cell array region Ar1 is configured or provided as a temporary memory region that requires fast readout and write-in of data. The second cell array region Ar2 is typically configured or provided as a standard memory region. Additionally, the boundary region B comprises elements to determine whether or not to use the first cell array region Ar1 as a temporary memory region.

The peripheral circuit region P comprises peripheral circuits including a control circuit CC which controls the readout/write-in/deletion of data for each memory cell of memory cell arrays Ar (Ar1 and Ar2), a row driving circuit RD, column driving circuit CD, and a sense amplifier SA. Furthermore, the memory cell arrays Ar (Ar1 and Ar2) are arranged within the memory cell region M, and the peripheral circuits are arranged in the peripheral circuit region P.

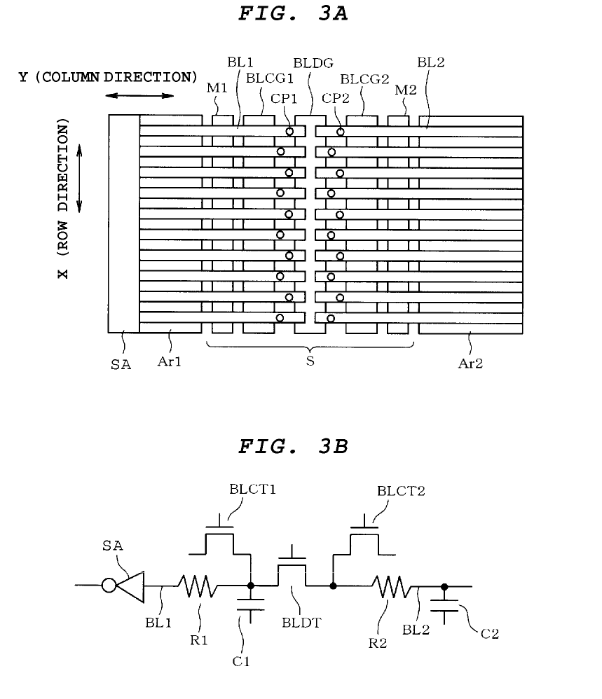

FIG. 2 is one example of a schematic diagram of the memory cell arrays, wherein multiple cell units CU of the memory cell arrays Ar within the memory cell region M are arranged in the form of a matrix. The first and second cell array regions Ar1 and Ar2 are arranged on either side of the boundary region B, which may perform a switching function to allow the first cell array region Ar1 to be used independently second cell array Ar2 as will described herein. The first cell array region Ar1 is arranged on the side of the sense amplifier SA in the peripheral circuit region P. The second cell array region Ar2 is arranged on the opposite side of the sense amplifier SA, across the boundary region B from the first cell array region Ar1.

Each cell unit UC comprises a selector gate transistor STD connected to the BL side of the bit lines, a selector gate transistor STS connected to the CSL side of the source lines, and multiple memory cell transistors MT (corresponding to memory cells) connected in series between the two selector gate transistors STS and STD (for example, when m=2 to the power of k; for example, 32).

A cell unit UC comprises the selector gate transistors STD and STS, and the memory cell transistor MT which are arranged parallel to the Y direction (column direction, channel length direction, bit line direction). One block BLK has cell units UC of the array is arranged along the X direction by a certain number of columns of cell units UC (row direction, channel width direction, word line direction). A certain number of the blocks BLK are arranged in the Y direction within the memory cell arrays Ar. As shown in FIG. 2, two columns of the block BLK are arranged in the first cell array region Ar1. Furthermore, any appropriate number, not only 2, of the block BLK1 can be arranged in the first cell array region Ar1. There are a lot of blocks in array region Ar2, too.

The selector gate transistors STD of the multiple cell units UC arranged in the X direction are each electrically connected with one selector gate line SGLD. This selector gate line SGLD is arranged in a way that corresponds to the block BLK1. Additionally, the selector gate transistor STS of the multiple cell units UC arranged in the X direction are electrically connected with one selector gate line SGLS. This selector gate line SGLS is also arranged in a way that corresponds to the block BLK1. The memory cell transistors MT arranged in the X direction are electrically connected to each other with one word line WL.

The sense amplifier SA shown in FIG. 1 is arranged at the edge of the first cell array region Ar1 of FIG. 2 (not shown at the top of FIG. 2) and is connected to the bit line BL. The sense amplifier SA connects the latch circuit that temporarily stores data during their readout. The first cell array region Ar1 comprises, for example, two blocks worth of memory cell and functions as the fast-operating region as described later. The rest of the blocks are arranged in the second cell array region Ar2.

The boundary region B comprises the bit line divider transistor BLDT that correspond to each bit line BL. The bit line charge-discharge transistors BLCT1 and BLCT2 are arranged on either side of the bit line divider transistor BLDT. These 3 transistors—BLDT, BLCT1, and BLCT2—comprise the standard transistor configuration as the selector gate transistors STD and STS do, and do not comprise floating gate electrodes. Therefore, the transistors BLDT, BLCT1, and BLCT2 arranged in the boundary region B can be formed having a gate length similar to that of the selector transistors in the first and second cell array regions Ar1 and Ar2, which minimizes the area increase needed to form the boundary region B, and reduces the number of masking steps required to form the memory.

The bit line BL is divided into 2 sections, one of which is the first bit line BL1 that extends from the sense amplifier SA (not shown in FIG. 2) to the upper area of the first cell array Ar1 to the bit line divider transistor source or drain, and the other one of which is the second bit line BL2 which extends, from the other source or drain of the bit line divider transistor, which forms the rest of the bit line. The bit line divider transistor BLDT is arranged at the division point of the bit line BL. The first bit line BL1 and the second bit line BL2 are each connected to the source and drain of this bit line divider transistor BLDT, respectively. Furthermore, the multiple bit line divider transistors BLDT arranged in the X direction are connected with the bit line divider gate line BLD, to which the gate electrode BLDG is also connected.

The bit line charge-discharge transistors BLCT1 and BLCT2 are each connected between the selector gate transistors STD located at the edges of the first and second cell array regions Ar1 and Ar2 and the bit line divider transistor BLDT, respectively. The bit line charge-discharge transistors BLCT1 and BLCT2 are each connected to the power supply lines M1 and M2 which extend orthogonally from the linear layout of the bit line divider transistor BLDT and the bit line charge-discharge transistors BLCT1 and BLCT2, and which share the same source/drain region with the nearby selector gate transistors STD for charging and discharging. Additionally, the multiple bit line charge-discharge transistors BLCT1 and BLCT2 arranged in the X direction are each connected to the bit line charge-discharge gate lines BLC1 and BLC2 together.

Due to this configuration, the bit lines BL1 and BL2 are electrically disconnected when the bit line divider transistor BLDT is switched to the off state. When the bit line divider transistor BLDT is switched on, the bit lines BL1 and BL2 are electrically connected. Additionally, when the bit line charge-discharge transistors BLCT1 and BLCT2 are switched on, either of the power supply lines M1 or M2 is connected to either of the bit lines BL1 or BL2, respectively, and the power line M1 (controlled by BLCT1) or M2 (controlled by BLCT2) can be charged and discharged.

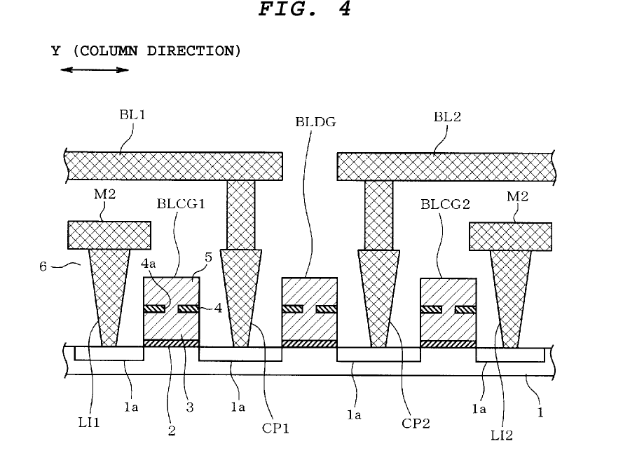

FIG. 3A is a two-dimensional diagram of the area from the sense amplifier SA to the first cell array region Ar1 as well as the boundary region B and the secondary cell array region Ar2 within the memory cell arrays Ar. FIG. 3B shows the equivalent circuit of the bit lines BL1 and BL2 connected to the sense amplifier SA and boundary region B.

Referring to FIG. 8, multiple element isolation areas SR are arranged on a semiconductor substrate 1 in this embodiment a silicon substrate spaced apart in the X direction and extending in the Y direction. For example, the element isolation areas SR are STI (shallow trench isolation) structures. The element arrangement area AA is arranged along the Y direction between the multiple element separation areas SR. The cell unit UC is arranged in the element arrangement area AA.

Referring again to FIG. 3A, the first memory cell region Ar1 is arranged near the sense amplifier SA, and the second memory cell region Ar2 is adjacent to the boundary region B positioned between it and the first memory cell region Ar1. Although the internal configurations of the first and second memory cell regions Ar1 and Ar2 are shown abbreviated from that shown in FIG. 3A, the cell unit UC comprising the memory cell transistor MT and selector gate transistors STS and STD is also located in the boundary region B. The boundary region B includes the gate electrode BLDG of the bit line divider transistor BLDT, on either side of which the gate electrodes BLCG1 and BLCG2 of the bit line charge-discharge transistors BLCT1 and BLCT2 are arranged in the X direction.

The sense amplifier SA is arranged in such a way as to straddle the multiple cell units UC in the X direction. The first bit line BL1 is connected to the sense amplifier SA, corresponding to each of the element arrangement areas AA. The first bit lines BL1 extends from the sense amplifier SA to the gate electrode BLDG of the bit line divider transistor BLDT of the boundary region B, and the second bit line BL2 extend further therefrom. The first and second bit lines BL1 and BL2 are thus divided at the gate electrode BLDG. The first bit line BL1 and the second bit line BL2 are each connected to the source/drain regions of the bit line divider transistor BLDT with the contact plugs CP1 and CP2, respectively, as will be further described with respect to FIG. 4. One of each source/drain region of the bit line charge-discharge transistors BLCT1 and BLCT2 is connected to the wiring conductors LI1 and LI2; the other of the source/drain is connected to the contact plugs CP1 and CP2.

The configuration of the connection between the first bit line BL1 and the second bit line BL2 of the above configuration is represented by the equivalent circuit shown in FIG. 3B. In other words, the first bit line BL1 and the second bit line BL2 each comprise the equivalent resistor components R1 and R2 as well as the equivalent capacitance components C1 and C2. These equivalent resistor components R1 and R2 and equivalent capacitance components C1 and C2 are distributed along the bit lines BL1 and BL2. Therefore, it is possible to write an equivalent circuit, wherein the equivalent resistor component R1 of the first bit line BL1, the bit line divider transistor BLDT, and the equivalent resistor component R2 of the second bit line BL2 is connected to the sense amplifier SA, and the equivalent capacitance components C1 and C2 are each connected between the first and second bit lines BL1 and BL2 and ground.

The sum of the equivalent resistor components R1 and R2 is equal to the equivalent resistor component of the bit line divider transistor BLDT when the bit line BL is not divided into BL1 and BL2. Likewise, the sum of the equivalent capacitance components C1 and C2 is equal to the equivalent capacitance component of the bit line divider transistor BLDT when the bit line BL is not divided into BL1 and BL2. Furthermore, the sizes of such equivalent resistor components and equivalent capacitance components correspond to the length measurement of the bit lines BL1 and BL2 due to the differences in their lengths.

FIG. 4 is a one example of schematic sectional diagram view of the configuration of the boundary region B, showing a cross section of the bit lines BL1 and B2 cut at the division point of the bit line BL along the Y direction. The element arrangement area AA (FIG. 8) of the silicon substrate 1 is located beneath the bit lines BL1 and BL2. The gate electrodes BLCG1 and BLCG2 of the bit line charge-discharge transistors BLCT1 and BLCT2, respectively, are located on either side of the gate electrode BLDG of the bit line divider transistor BLDT.

The gate electrodes BLDG, BLCG1, and BLCG2 are formed from a layered stack of gate insulating film 2, polysilicon film 3, interelectrode insulating film 4, and polysilicon film 5 arranged on the upper surface of the silicon substrate 1. Some layers of insulating films are not shown in this figure. The opening 4a is arranged at the interelectrode insulating film 4, creating a short-circuit (conductive pathway) between the polysilicon films 3 and 5. An impurity diffusion area 1a is located in substrate 1 and extends between the gate electrodes BLDG, BLCG1, and BLCG2, which diffusion area 1a function as the source/drain regions. Additionally, as interlayer insulating film 6 is arranged so as to cover the gate electrodes BLDG, BLCG1, and BLCG2.

Overlying and connecting to the impurity diffusion areas 1a on either side of the gate electrode BLDG are contact plugs CP1 and CP2, which are electrically connected to the edges of the first bit line BL1 and the second bit line BL2 at the upper (opposed to diffusion area 1a) end thereof. The impurity diffusion areas 1a of the gate electrodes BLCG1 and BLCG2 on the side thereof opposite to gate electrode BLDG are connected to conductors LI1 and LI2 which are electrically connected to the power supply lines M1 and M2 on their upper end.

Next, the function of this configuration is explained.

In regards to this configuration, first of all, since the first bit line BL1 and second bit line BL2 are electrically connected via the bit line divider transistor BLDT when the bit line divider transistor BLDT is switched on, the same operations as before are possible. FIG. 3A and FIG. 3B show this configuration. The time constant τ (1+2) when the first and second bit lines BL1 and BL2 are connected is expressed as below:

τ(1+2)=(R1+R2)×(C1+C2)

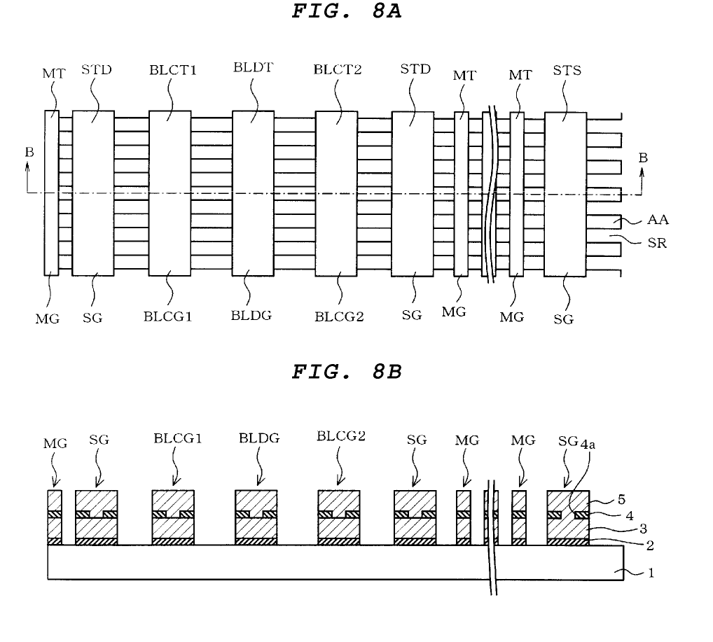

The conventional equivalent readout time of this configuration is shown in FIG. 6C. This FIG. shows the bit line voltage VBL of the charging-discharging bit lines BL1 and BL2. The bit line voltage VBL reaches a certain voltage at the time tp3 after the pre-charge time Tc3 has elapsed from the charging starting point t0; then, at the time tr3 after the fixed time T0 has elapsed, the readout of the memory cell status starts. The readout is completed at the time ts3 after the readout processing time Tse3 has elapsed.

Next, when the bit line divider transistor BLDT is switched on, meaning the same as with the conventional equivalent configuration, the configuration wherein the bit line charge-discharge transistors BLCT1 and BLCT2 are switched on, charging the first and second bit lines BL1 and B12 by the sense amplifier SA as well as the power supply lines M1 and M2, is explained.

In this case, since the lengths of the bit lines are the same as the previous configuration, the time constant τ remains the same as well. However, the charging time is shortened because the bit lines BL1 and BL2 are also charged by the power supply lines M1 and M2 via the bit line charge-discharge transistors BLCT1 and BLCT2.

As shown in FIG. 6B, the bit line voltage VBL reaches a certain voltage at the time tp2 after the pre-charge time Tc2 (<Tc3) has elapsed from the charging starting point t0; then, at the time tr2 after the fixed time T0 has elapsed, the readout starts. The data readout starts at the time ts2 after the time that it takes for the sense amplifier SA to operate Tse2 (=Tse3) requiring the stability of VBL has elapsed. In this case, the time delays before the readout starts Tr2 and Tr3 are the same during discharging since the physical configuration is the same. Therefore, the operation speed is increased by the shortened charging time Tc2.

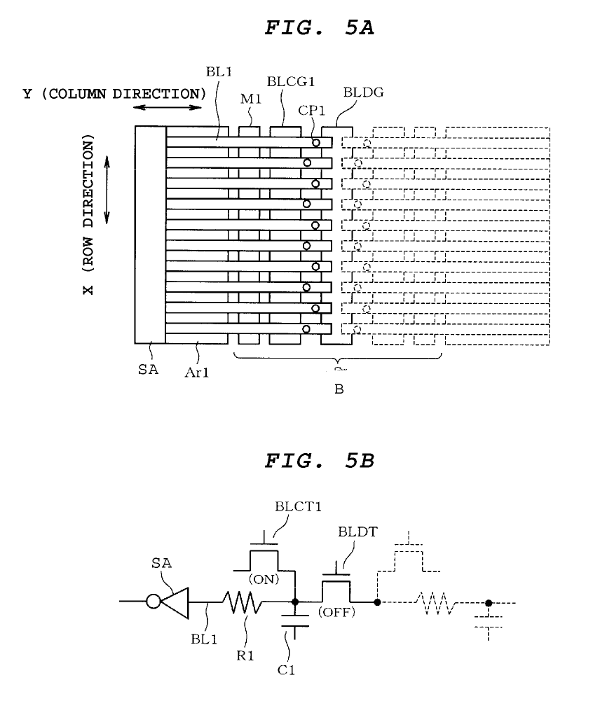

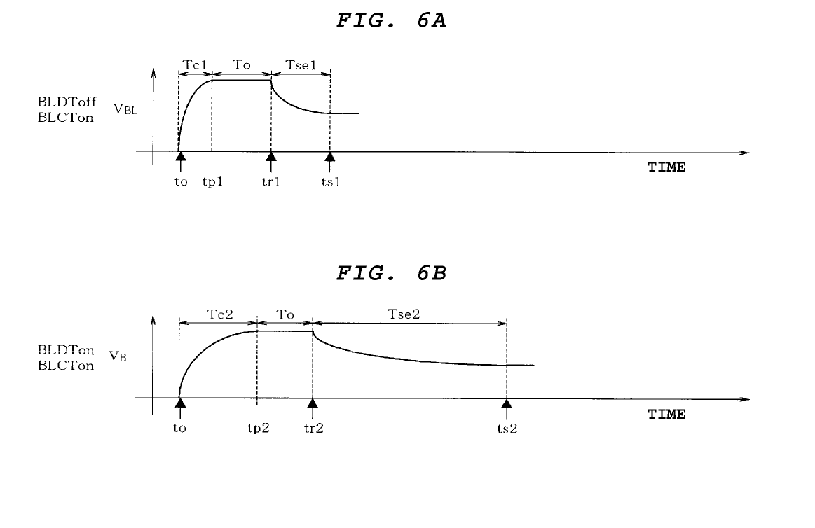

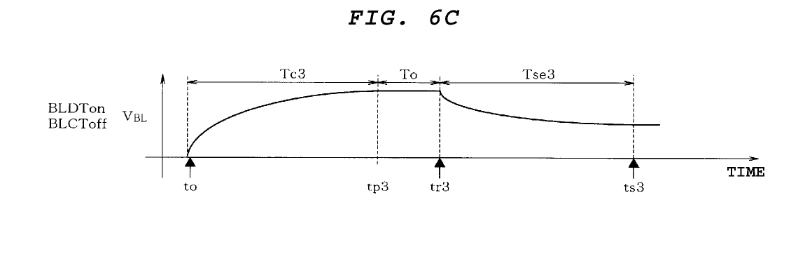

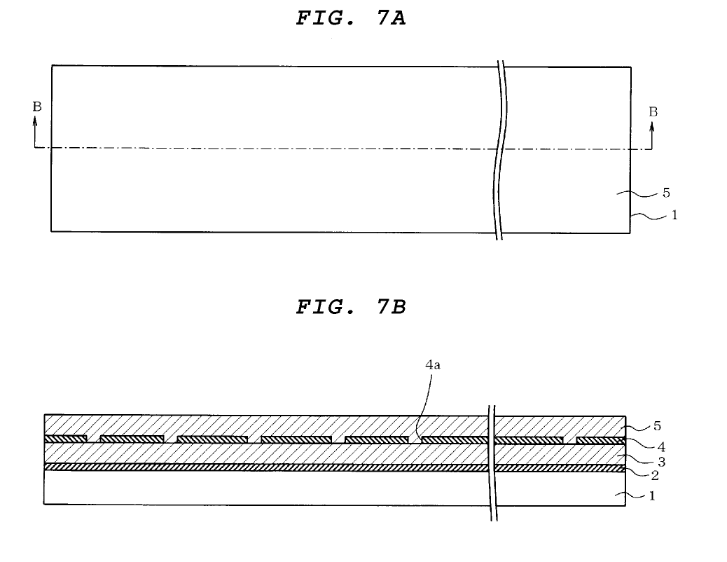

Next, the configuration wherein the bit line divider transistor BLDT is switched off and wherein the second bit line BL2 is disconnected, i.e., using only the first bit line BL1 and thus only first memory array Ar1, is explained. FIG. 5A and FIG. 5B show this configuration. In other words, essentially, the memory cell transistor MT in the second memory cell region Ar2 is not used. In this case, the time constant τ (1) of the first bit line BL1 is expressed as:

τ(1)=R1×C1

Furthermore, the resistance element values R1 and R2 and capacitance element values C1 and C2, which are the deciding factors of the time constant τ (1), closely correlate to the lengths of the bit lines BL1 and BL2. Therefore, for example, assuming that the overall length of the bit line L is equal to the sum of the bit lines BL1 and BL2, the length of the first bit line BL1 is expressed as 1/n of the overall length. In this case, the resistance element R1 of the first bit line BL1=(R1+R2)/n and the capacitance element C1=(C1+C2)/n. Consequently, the time constant τ (1) of the first bit line BL1 is expressed as:

τ(1)=(1+2)/n²

Hence, if the length of the first bit line BL1 is set to be one half of the overall length L (L/2) of the total bit line length, the time constant τ (1) is a quarter of the full length bit line. According to the value n, which corresponds to the dividing rate, the charging and discharging time can be shortened by a power of 2.

As a result, as shown in FIG. 6A, a desired voltage is reached at the time tp1 after the pre-charge time Tc1 (<Tc2) has elapsed from the charging starting time t0; then, at the time tr1 after the fixed time T0 has elapsed, the readout of the memory cells starts. The readout is completed at the time ts1 after the data readout time Tse1 (<Tse2) has elapsed. In this case, the physical length of the bit line is shorter when discharging, the time constant τ (1) becomes smaller, and the time delay before readout starts Tr1 is shorter than Tr2 or Tr3. Hence, the overall operation time is also shortened. Furthermore, the charging time (pre-charge time) can be shortened by switching the bit line charge-discharge transistor BLCT1 on, charging the source thereof via the power supply M1.

As explained, the first memory cell region Ar1 can be used as a temporary memory region when the memory is selected to be used as the fast-operating memory by switching the bit line divider transistor BLDT off. Data can first be stored in the temporary memory region during data transfer with the CPU, for example, then recalled again to be stored in the second memory cell region Ar2. Consequently, the time that it takes to access or write data is shortened, allowing for faster operation.

In this case, it is possible to use the number of blocks of the first memory cell region Ar1 as a temporary memory region. At this time, the temporary memory size is appropriate for the overall memory capacity. The size of this temporary memory region can be customized by changing the position of the bit line divider transistor BLDT along the length of the bit line BL to change the relative length of BL1 and BL2 at the boundary region B.

Next, the manufacturing steps of this configuration are explained, using FIG. 7A to FIG. 23C.

First of all, the configuration shown in FIGS. 7A and 7B and its manufacturing steps are briefly explained. FIGS. 7A and 7B show, with the boundary region B in the middle, a part of the first memory cell region Ar1 and the second memory cell region Ar2. FIG. 7A is a plan view and FIG. 7B is a cross section along the B-B line in FIG. 7A.

As shown in FIG. 7B, agate insulating film 2 is arranged on the silicon substrate 1, over which a polysilicon film 3 is arranged. The polysilicon film 3 is arranged as a floating gate electrode of the memory transistor MT. Thereafter, an interelectrode insulating film 4, then an polysilicon film 5, are formed. For the interelectrode insulating film 4, a material such as an ONO (oxide-nitride-oxide) film is used. Additionally, the opening 4a for short-circuiting (electrically connecting) the polysilicon above and below insulating film 4 is formed in the interelectrode insulating film 4 before the formation of the polysilicon film 5 thereover.

Next, as shown in FIG. 8A and FIG. 8B, the polysilicon film 5, the interelectrode insulating film 4, the polysilicon film 3, and the gate insulating film 2 are etched to make the individual gate electrodes MG, SG, BLDG, BLCG1, and BLCG2. Consequently, the element arrangement area AA and the element isolation area SR on the silicon substrate 1 are exposed as shown in FIG. 8A. At this point, although not shown in FIG. 8B, an impurity diffusion area 1a, which is to be the source/drain area shown in FIG. 4, is arranged on the surface of the silicon substrate 1 between the gate electrodes MG, SG, BLDG, BLCG1, and BLCG2 by ion implantation of dopants (impurities), etc.

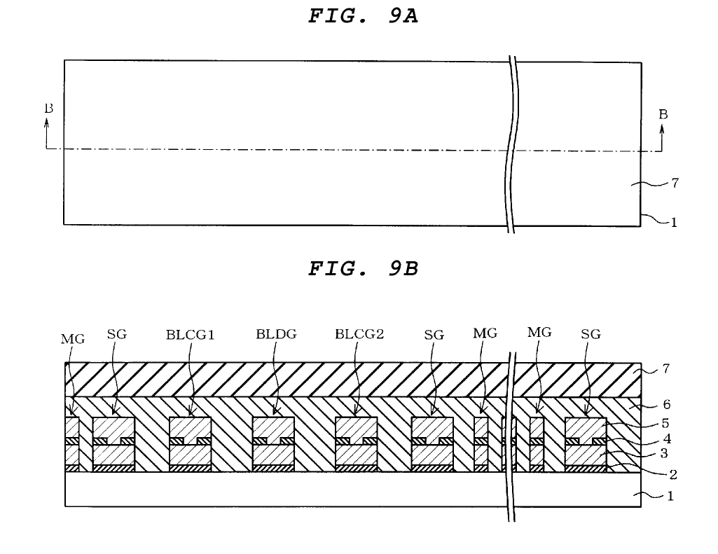

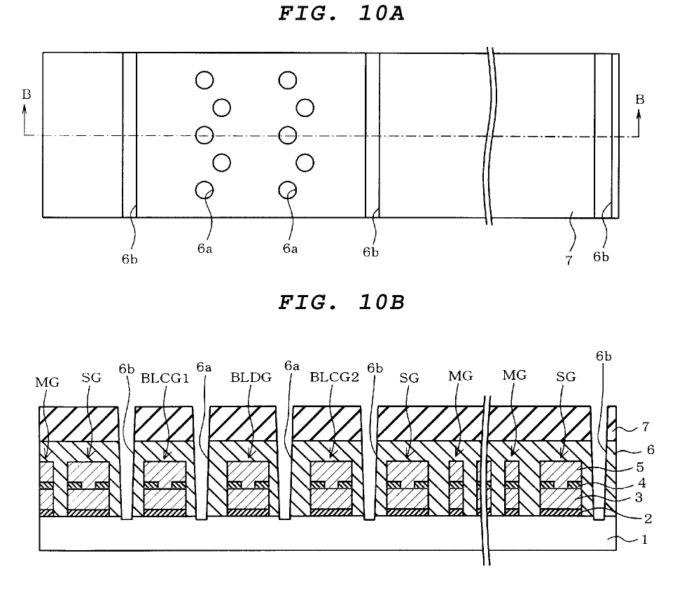

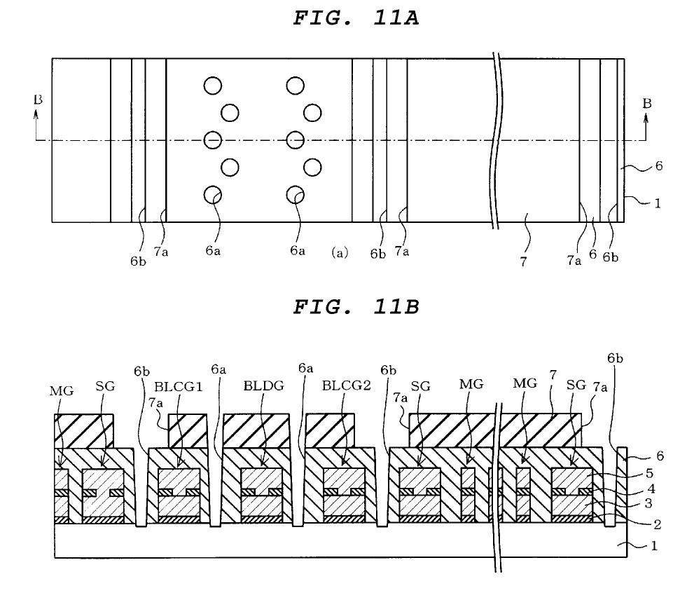

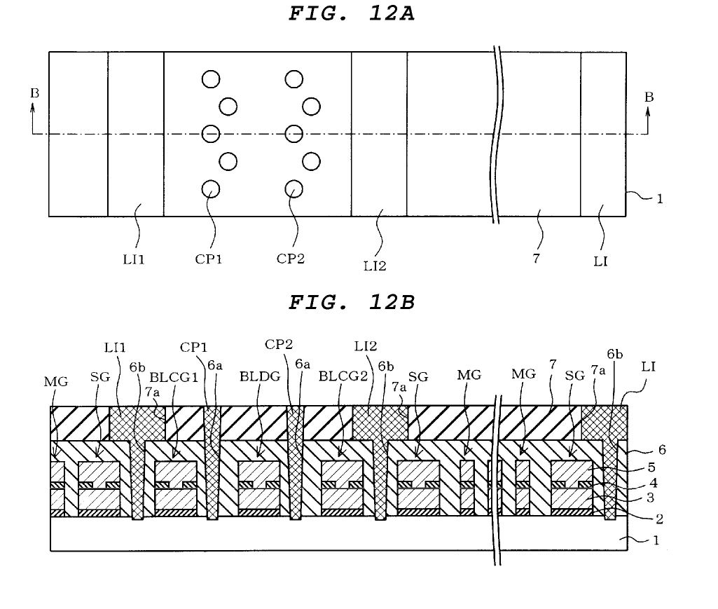

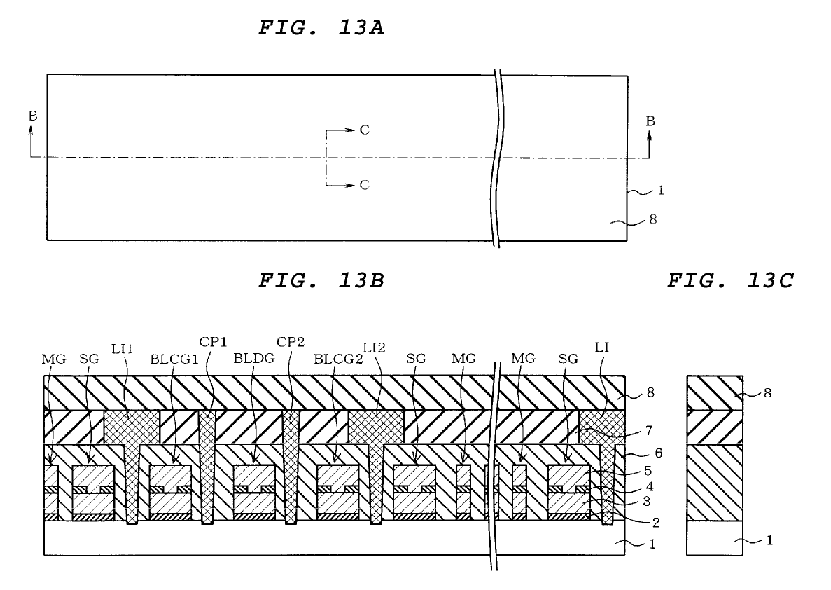

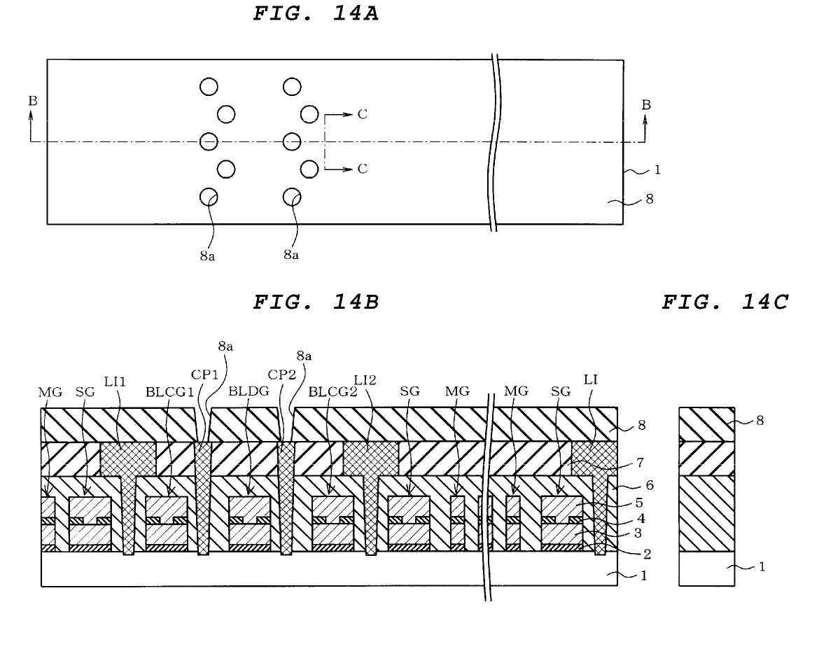

Next as shown in FIG. 9A and FIG. 9B, an interlayer insulating film 6, such as a silicon oxide layer, is deposited so as to be embedded into the gaps between the gate electrodes MG, SG, BLDG, BLCG1, and BLCG2 and planarized. The interlayer insulating film 7 for a wiring pattern arrangement is then formed thereover.

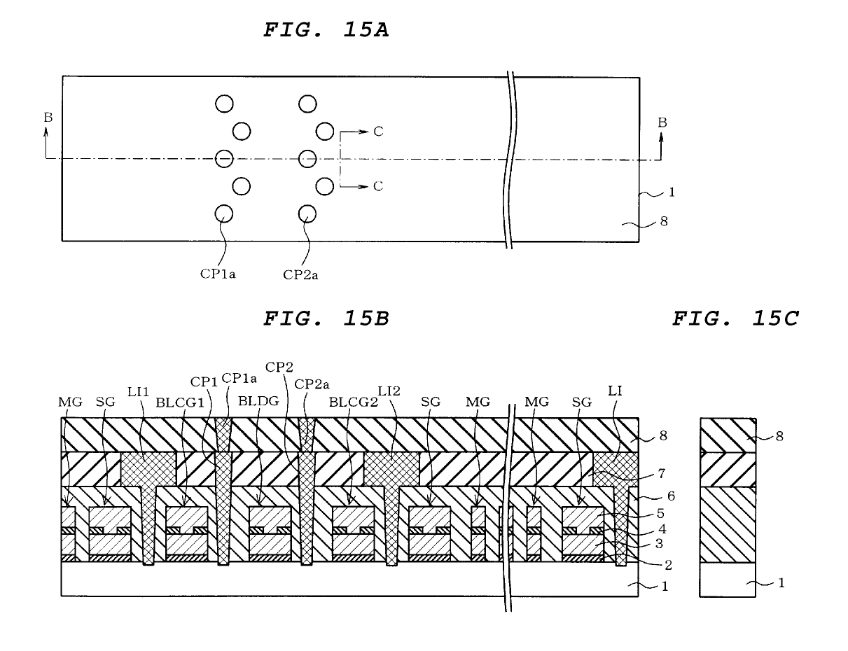

Next, as shown in FIG. 10A and FIG. 10B, contact holes 6a and contact grooves 6b are formed, which pierce through the interlayer insulating films 7 and 6 to reach the surface of the silicon substrate 1 Thereafter, contact plugs CP1 and CP2, are formed in contact holes 6a positioned on either side of the gate electrode BLDG, and electrically connected to the impurity diffusion area 1a, corresponding to the bit lines BL1 and BL2, respectively. Additionally, the contact plugs CP1 and CP2 are arranged in a staggered (zigzag) layout, with the distance from the other nearby element arrangement areas AA being taken into consideration.

The contact groove 6b is arranged so as to enable interconnection of the adjacent impurity diffusion areas 1a of the element arrangement areas AA to each other on the connection conductors LI1 and LI2 located on the other side of the gate electrodes BLCG1 and BLCG2. The contact groove 6b as the source contact of the selector gate transistor STS is arranged simultaneously.

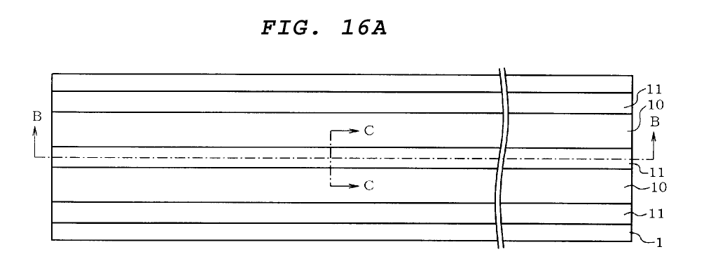

Next, as shown in FIG. 11A and FIG. 11B, a pattern 7a for forming wiring layers therein is formed by etching the upper layer of the interlayer insulating film 7, in areas overlying the contact groove 6b. This allows the connection conductors LI1, LI2, and LI to have a dual damascene structure.

Next, as shown in FIG. 12A and FIG. 12B, the wiring metal film is embedded within the contact hole 6a, the contact groove 6b, and the pattern 7a to form the contact plugs CP1 and CP2 as well as the connection conductors LI1, LI2, and LI. In this method, the entire upper surface of structure of FIG. 11B is covered once with a wiring metal film, and then the residues on the interlayer insulating film 7 are removed by CMP (chemical mechanical polishing) to the surface of interlayer insulating film 7 as shown in FIGS. 12A and 12B.

Next, as shown in FIG. 13A and FIG. 13B, an interlayer insulating film 8 is arranged on the upper surface of the interlayer insulating film 7, in which the contact plugs CP1 and CP2 as well as the connection conductors LI1, LI2, and LI are formed. Furthermore, FIG. 13C shows a cross section along the line C-C in FIG. 13A as well as the gate electrode BLCG2.

Next as shown in FIG. 14A to FIG. 14C, a via-hole 8a is etched through the interlayer insulating film 8. The via-hole 8a is arranged so as to correspond to the contact plugs CP1 and CP2 as shown in FIG. 14A.

Next, as shown in FIG. 15A to FIG. 15C, the wiring metal film is formed inside the via-hole 8a to create the via-plugs CP1a and CP2a. Damascene technology is also used for the arrangement of these via-plugs CP1a and CP2a, wherein the wiring metal film is formed on the interlayer insulating film 8, embedding the via-hole 8a, and the wiring metal film covering the interlayer insulating film 8 is removed by CMP.

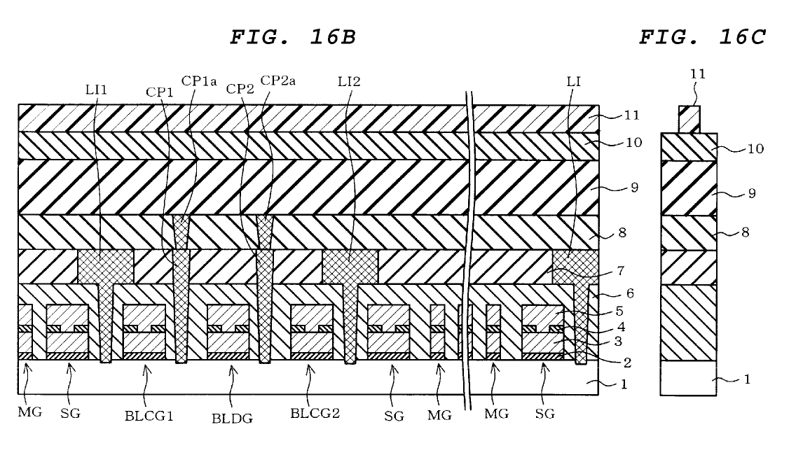

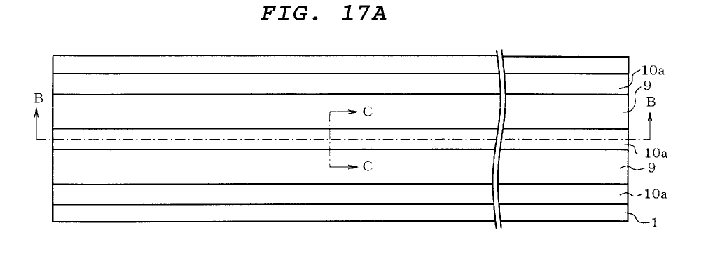

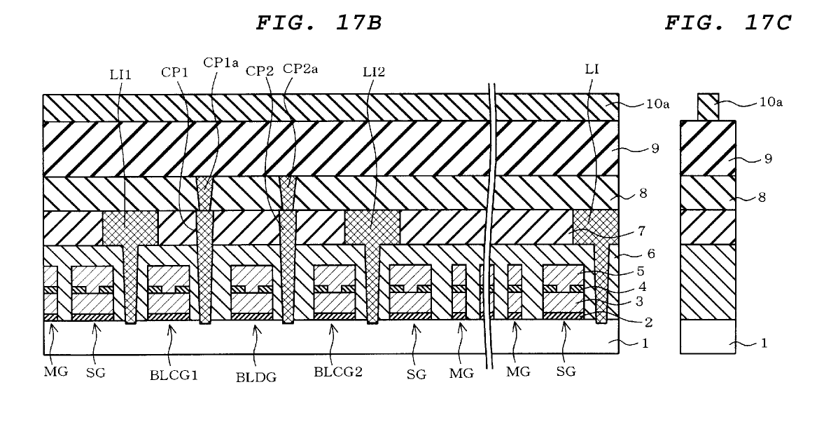

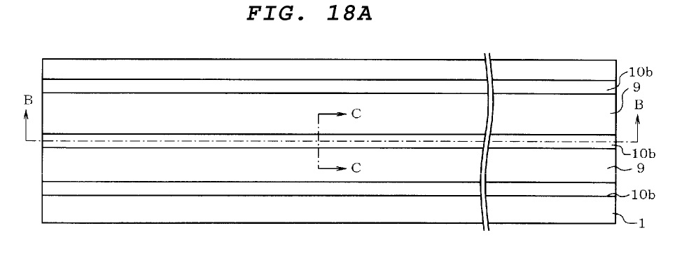

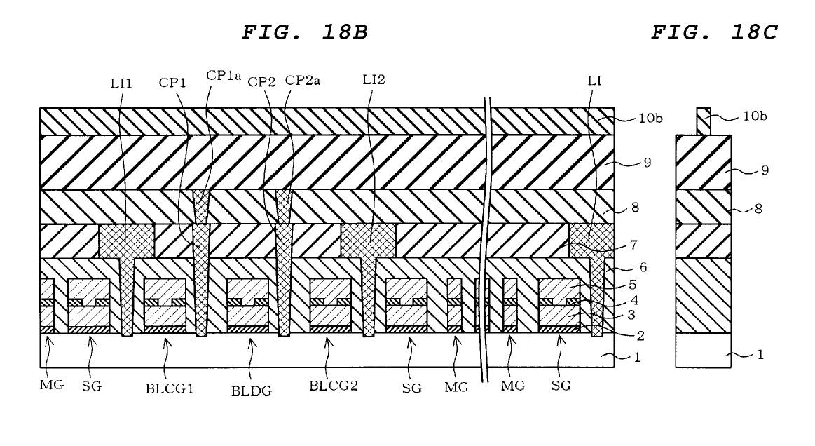

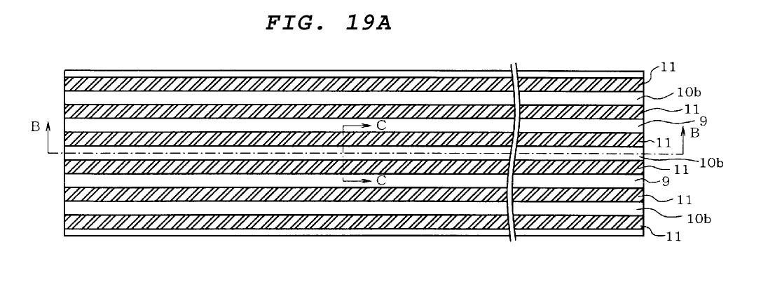

Next, as shown in FIG. 16A to FIG. 16C, an interlayer insulating film 9 is arranged on the interlayer insulating film 8; furthermore, an amorphous silicon film 10 is formed on the interlayer insulating film 9. A patterned resist pattern 11 is formed on the amorphous silicon film 10. The width of the pattern of the resist 11 is 2L when the width of the bit lines BL1 and BL2 is L as shown in FIG. 16C.

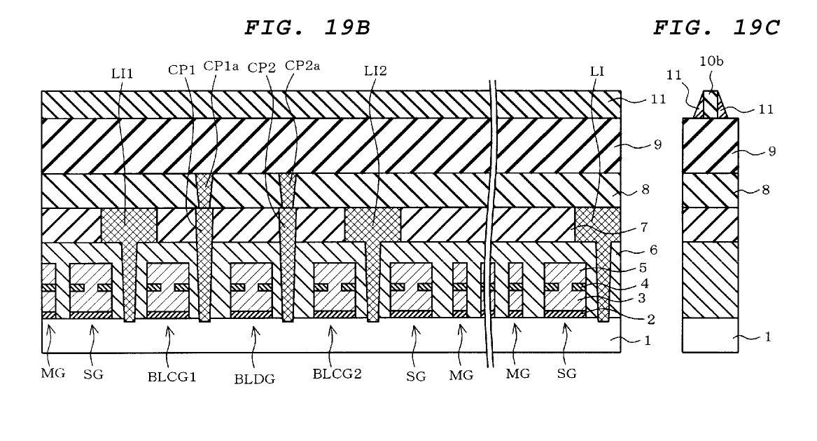

Next, as shown in FIG. 17A to FIG. 17C, the amorphous silicon material 10 is patterned to form a sacrificial core 10, using the resist pattern 11 as a mask. Consequently, the width of the core material 10a arranged in this way is 2L.

Next, as shown in FIG. 18A to FIG. 18C, slimming is performed on the core material 10a by wet etching from both sides by an equivalent width of L/2. This results in the core material 10b, whose width is L, as shown in FIG. 18C.

Next, as shown in FIG. 19A to FIG. 19C, a silicon nitride film having a thickness of L is arranged so as to cover the core material 10a; excess film is removed by anisotropic dry etching using the RIE (reactive ion etching) method until the upper surface of the core material 10a is exposed, with the pattern 11 in the form of a tapered spacer remaining on both sides of the core material 10a.

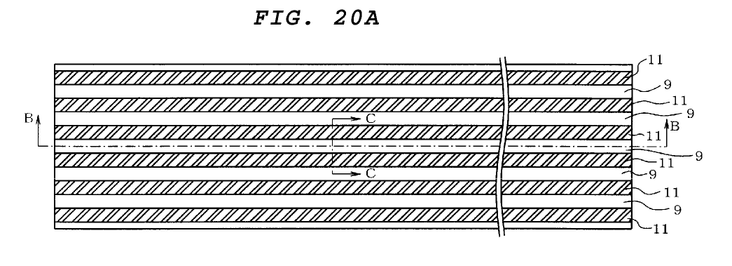

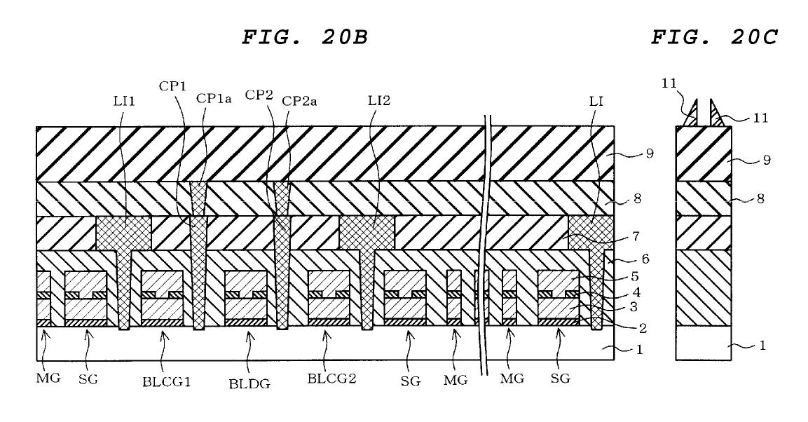

Next, as shown in FIG. 20A to FIG. 20C, the remaining core material 10a between the SiN pattern 11 is selectively removed by wet etching. This results in the pattern 11 being in the form of opposed tapered spacers having a width of L. Consequently, the patterns 11 shown in FIG. 20A have a width of L and are spaced apart by an interval of L.

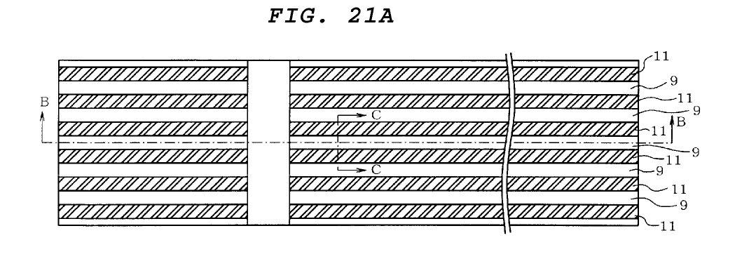

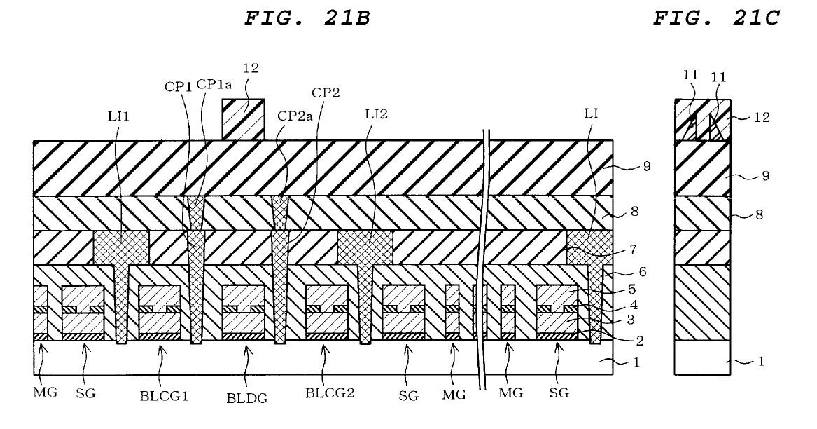

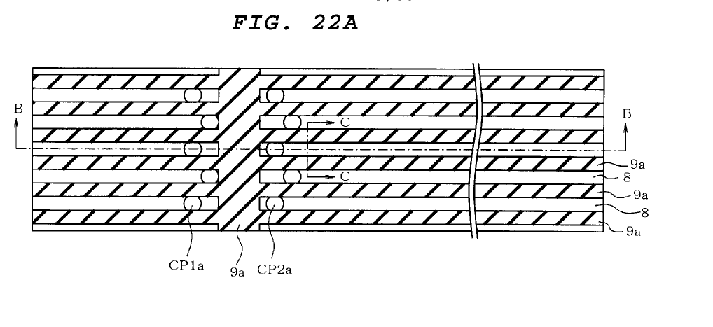

Next, as shown in FIG. 21A to FIG. 21C, a photo resist pattern 12 is formed. The pattern 12 is formed so as to cover the immediate upper surface of the gate electrode BLDG of the bit line divider transistor BLDT, functioning as the resist pattern to divide the bit line and the pattern 11 features.

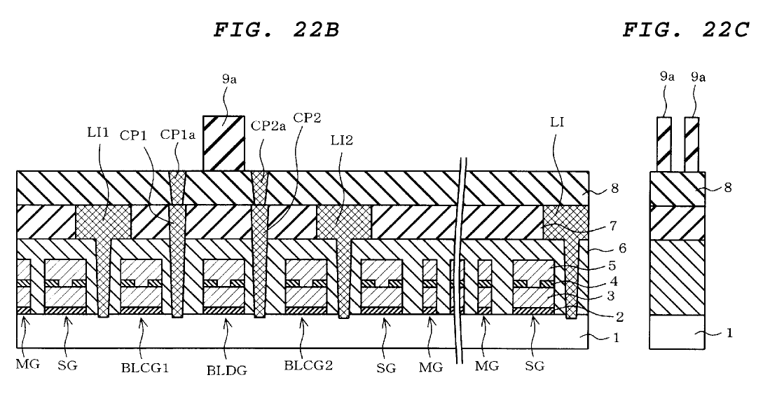

Next, as shown in FIG. 22A to FIG. 22C, the interlayer insulating film 9 is etched, using the photo resist pattern 12 and the pattern 11 as masks. As shown in FIG. 22A, the interlayer insulating film 9a remains at the dividing point of the bit line BL, and concave areas (recesses) corresponding to the position of the bit lines BL1 and BL2 are formed. Additionally, the upper surface of the via-plugs CP1a and CP2a are exposed at the concave areas of the interlayer insulating film 9a.

Next, as shown in FIG. 23A to FIG. 23C, a wiring metal film is deposited on the entire surface of this configuration, which is then processed by damascene processing so that the wiring metal film is embedded inside the concave area of the interlayer insulating film 9a. The first bit line BL1 and second bit line BL2 are thus embedded in the concave regions of the interlayer insulating film 9a. Additionally, the first bit line BL1 and second bit line BL2 are each electrically connected to the via-plugs CP1a and CP2a, respectively.

As described above, with a pitch having a width of L to one having a width of 2L, which allows light exposure, the bit lines BL1 and BL2 can be embedded inside the interlayer insulating film 9 by using sidewall transfer patterning technology in manufacturing. Furthermore, because the interlayer insulating film 9a is left on the immediate upper surface of the gate electrode BLDG of the bit line divider transistor BLDT, a configuration wherein the first bit line BL1 and the second bit line BL2 are divided can be arranged by damascene technology.

Additionally, the bit lines BL1 and BL2 are arranged in an extremely fine pattern beyond the light exposure limit by the use of sidewall transfer patterning technology, causing the resistance element and capacitance element of the bit lines BL1 and BL2 to increase. It is effective to use a configuration, such as this embodiment, wherein the operation is carried out with the divided bit line BL1.

### Second Embodiment

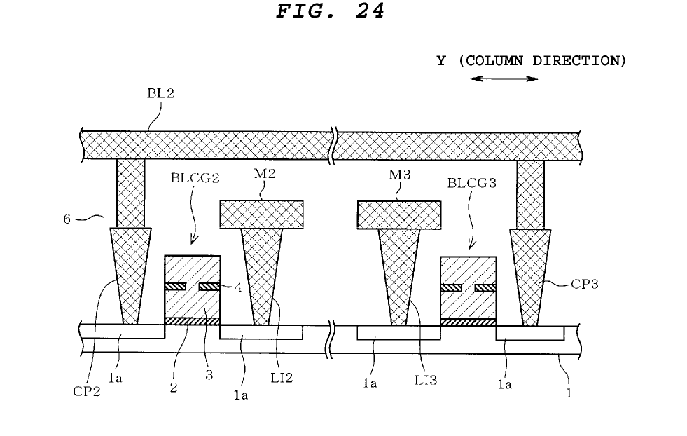

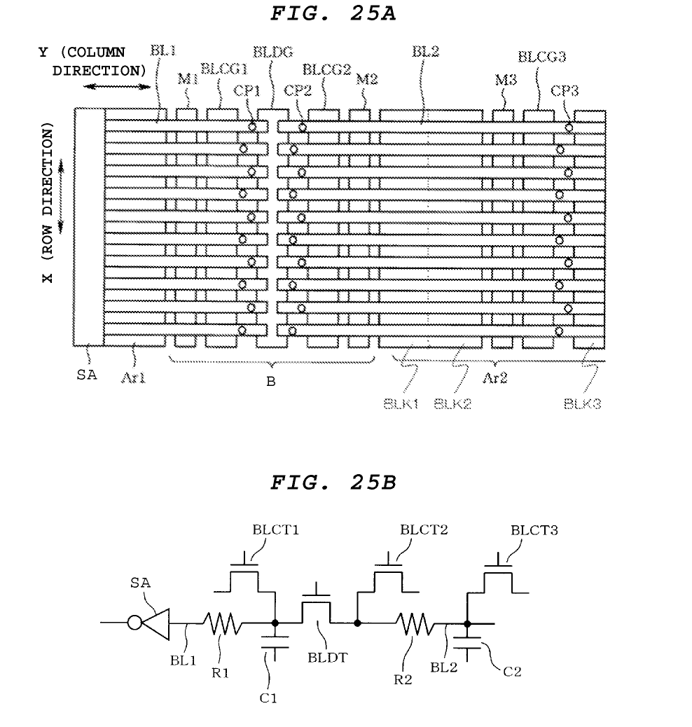

FIG. 24 and FIGS. 25A and 25B show a second embodiment hereof. The difference from the first embodiment is that multiple bit line charge-discharge transistors BLCT2 are arranged within the region of the divided bit line BL2.

As shown in FIG. 24, in addition to the bit line charge-discharge transistor BLCT2 in the first embodiment (FIG. 4), the bit line charge-discharge transistor BLCT3 is provided in the second memory cell region Ar2 which corresponds to the second bit line BL2 and spaced from bit-line charge-discharge transistor BLCT2. The contact plug CP3 is arranged in the impurity diffusion area 1a, which is the drain/source region of one side of this bit line charge-discharge transistor BLCT3, and is connected to the second bit line BL2. Furthermore, the connection conductor LI3 is arranged in the impurity diffusion area 1a of the other side of the bit line charge-discharge transistor BLCT3, and is connected to the power supply line M3. FIG. 25A and FIG. 25B, as corresponding figures to FIG. 3A and FIG. 3B, pertain to the configuration of FIG. 24.

The charging capability of the second bit line BL2 can be further increased by the this configuration. When the bit line divider transistor BLDT is switched on, and the first and second bit lines BL1 and BL2 are electrically connected, the bit lines BL1 and BL2 can be charged more rapidly, allowing for a faster operation speed.

Additionally, the number of bit line charge-discharge transistors BLCT to be arranged can be changed appropriately to achieve stable as well as fast charging and discharging operations. Furthermore, as for the locations of the bit line charge-discharge transistors BLCT, anywhere near the selector gate transistor STD in the second memory cell region Ar2 is appropriate.

### Third Embodiment

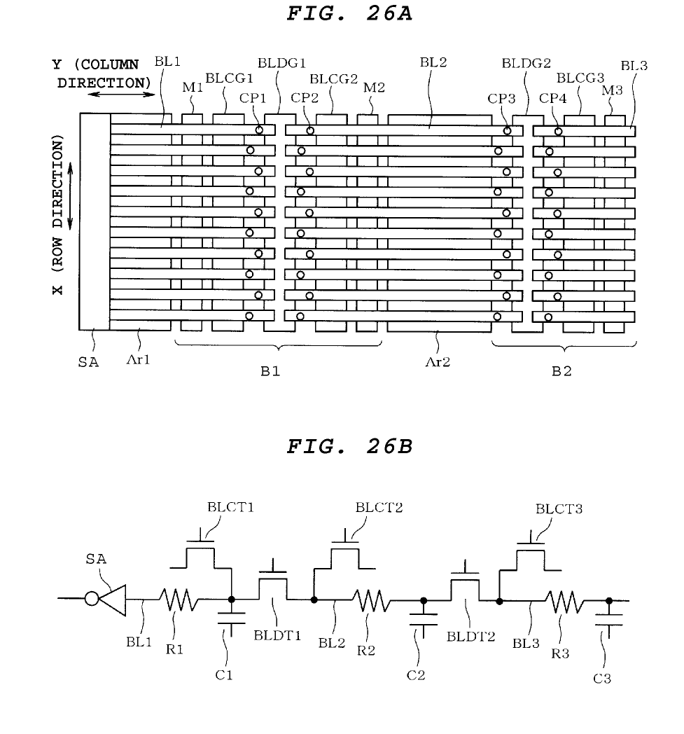

FIG. 26A and FIG. 26B show the third embodiment hereof. The difference from the first embodiment (FIG. 4) is that the bit line is divided into 3 or more sections. The first bit line BL1, the second bit line BL2, and the third bit line BL3 are shown. As shown in FIG. 26A, the first to third memory cell regions Ar1 through Ar3 are arranged in a way that corresponds to the bit lines BL1 to BL3. Additionally, as shown in FIG. 26B, the boundary regions B1 and B2 are arranged between the first to third memory cell regions Ar1 to Ar3.

As shown in FIG. 26A, the boundary region B1 comprises the bit line divider transistor BLDT1, the bit line charge-discharge transistors BLCT1 and BLCT2, and the gate electrodes BLDG1, BLCG1, and BLCG2 in the same way as the first embodiment. Also, the boundary region B2 comprises the bit line divider transistor BLDT2, the bit line charge-discharge transistor BLCT3, and the gate electrodes BLDG2 and BLCG3. The bit line charge-discharge transistor BLCT3 is arranged so as to correspond to the third bit line BL3 in the third memory cell region Ar3.

When using the first memory cell region Ar1, the bit line divider transistor BLDT1 is switched off to maximize the efficiency of the first bit line BL1, and data are processed with the second bit line BL2 and the third bit line BL3 disconnected. Consequently, the operation speed can correspond to the time constant τ (1) of the first bit line BL1; also the first bit line BL1 can be charged rapidly during the readout.

Furthermore, when using the second memory cell region Ar2, the bit line divider transistor BLDT1 is switched on, and the bit line divider transistor BLDT2 is switched off. Therefore, the first bit line BL1 and the second bit line BL2 are connected and the third bit line BL3 is disconnected.

Additionally, when using the third memory cell region Ar3, the bit line divider transistors BLDT1 and BLDT2 are switched on, and all the bit lines BL1 to BL3 are connected.

In summary, the overall operation speed can be improved by this configuration, wherein the operation time is kept to a minimum by selecting which of the first through third memory cell regions Ar1 through Ar3 are to be used.

### Fourth Embodiment

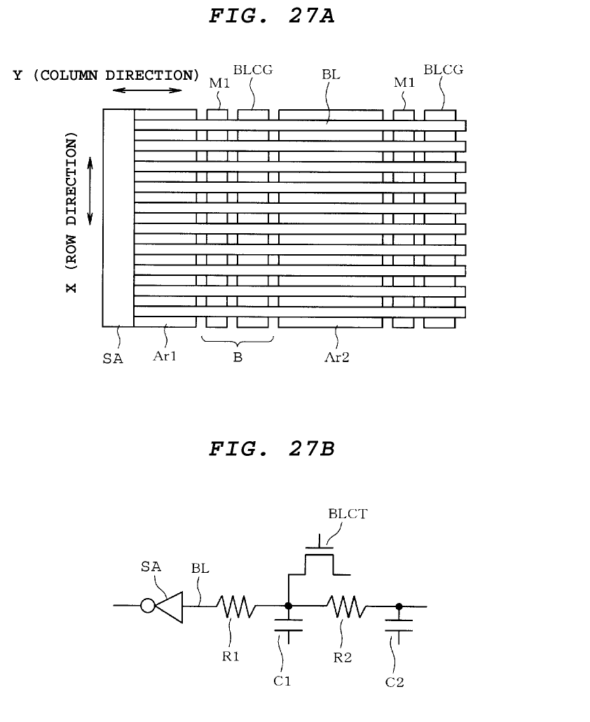

FIG. 27A and FIG. 27B show a fourth embodiment hereof. The difference from the first embodiment (FIG. 4) is that the standard bit line BL is not divided and no bit line divider transistor BLDT is provided. In other words, this configuration comprises the first and second memory cell regions Ar1 and Ar2 that are divided by the boundary region B that comprises the bit line charge-discharge transistor BLCT.

As shown in FIG. 27 A, the boundary region B is located between the selector gate transistors STD of the first and second memory cell regions Ar1 and Ar2, and the gate electrode BLCG of the bit line charge-discharge transistor BLCT. One side of the source/drain region of the bit line charge-discharge transistor BLCT is connected to the power supply line M1; the other side is connected to the bit line BL via the selector gate transistor STD.

Consequently, when the bit line BL is charged during readout, it can also be charged by the sense amplifier SA and the power supply line M1 via the bit line charge-discharge transistor BLCT, allowing for a fast operation speed.

Furthermore, the boundary region B can also be located anywhere between the selector gate transistors STD within the second memory cell region Ar2, besides the stated location. Also, to the bit line BL the charging and discharging time can be shortened by arranging multiple boundary regions B.

### Other Embodiments

Other embodiments in addition to those described are also possible.

Any number of bit line charge-discharge transistors BLCT can be arranged, according to the required operation speed, since they shorten the charging time of the bit line BL. Also, any number of bit line divider transistors BLDT can be arranged anywhere, according to the purpose of the memory cell of the memory cell array Ar, whether it is to be used as the capacitance for a fast operation or for the final memory area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A semiconductor memory device, comprising:
a first memory cell array and a second memory cell array each having a plurality of memory cells therein, each memory cell comprising a plurality of memory cell transistors interconnected in series and connected selectively electrically through a selector transistor to a bit line; and
a boundary region interposed between the first memory cell array and the second memory cell array, wherein the boundary region includes a bit line charge-discharge transistor positioned between a bit line of the first memory cell and a bit line of the second memory cell.

2. The semiconductor memory of claim 1, wherein the boundary region includes a bit line dividing transistor positioned between the bit line charge-discharge transistor and a bit line of the second array of memory cells, wherein the bit line dividing transistor is configured to switch between on and of f states to selectively connect the bit line of the second memory cell array to a bit line of the first memory cell array.

3. The semiconductor memory device of claim 2, wherein the boundary region includes a second bit line charge-discharge transistor, and the bit line charge-discharge transistor and the bit line charge-discharge transistor are disposed on adjacent to the bit line dividing transistor.

4. The semiconductor memory of claim 2, further including a second selector gate transistor interposed between a memory cell transistor and the bit line charge-discharge transistor.

5. The semiconductor memory device of claim 1, wherein a common source line is connected between adjacent memory cells.

6. The semiconductor memory device of claim 1, further including a third memory cell array, along the bit line thereof, and
a second boundary region interposed between the second memory cell array and the third memory cell array, wherein the second boundary region includes a second bit line charge-discharge transistor positioned between the bit line of the second memory cell and a bit line of the third memory cell.

7. The semiconductor memory device of claim 6, further including a second bit line dividing transistor positioned between the bit line charge-discharge transistor and a bit line of the third array of memory cells, wherein the second bit line dividing transistor is configured to switch between on and of f states to selectively connect the bit line of the third memory cell array to a bit line of the second memory cell array.

8. The semiconductor device of claim 1, wherein the length of the bit line of the first memory cell and the length of the bit line of the second memory cell are the same, and the time constant of the bit line of the first memory cell when the bit line of the first memory cell is not electrically connected to the bit line of the second memory cell is one quarter the time constant of the bit lines together when the bit lines are connected together through the bit line dividing transistor.

9. The semiconductor memory of claim 1, further including second bit line charge-discharge transistor, wherein the second bit line charge-discharge transistor is electrically connected in series with the bit line dividing transistor and the bit line of the second memory cell.

10. The semiconductor memory of claim 9, further including a third bit line discharge member interconnected to the bit line of the second memory cell.

11. A method of providing a non-volatile semiconductor memory having write and read operations comprising the steps of:
selectively electrically isolating a first memory array and a second memory array with a switchable transistor electrically located therebetween to read or write data to the first memory array at a speed faster than possible when the first and second memory arrays are electrically connected.

12. The method of claim 11, further including the step of writing data into the first memory array when the first memory array is electrically isolated from the second memory array.

13. The method of claim 12, further including the step of
writing the data to the second memory array when the first and second memory arrays are electrically connected.

14. The method of claim 11, wherein the first and second memory arrays are selectively electrically connected together through a bit line.

15. The method of claim 14, further including the steps of charging the bit line of the second array from a source other than the bit line.

16. The method of claim 11, further including the step of connecting a sense amplifier to the bit line of the first memory array but not directly to the bit line of the second memory array.

17. A nonvolatile semiconductor memory device comprising:
multiple cell units, arranged in a matrix configuration in a memory cell region that comprise multiple memory cell transistors connected in series, and a first and a second selector gate transistors, a different selector gate transistor connected to opposed ends of the multiple memory cell transistors;
a bit line that is arranged in an extending direction of the multiple cell units and that is connected to a drain of one of the selector gate transistors of each of the cell units;
a source line that extends in a direction perpendicular to the multiple cell unit and that is connected to the source of the other of the selector gate transistor of each of the cell units; and
a bit line charge-discharge transistor connected to the bit line and the drain side of at least one of the selector gate transistors of the multiple cell units.

18. The nonvolatile semiconductor memory device according to claim 17, wherein
the bit line comprises a first bit line, one of whose ends is connected to a sense amplifier, and at least one second bit line arranged adjacent to the other end of the first bit line, and
a bit line divider transistor is arranged on a drain side region of one of the selector gate transistors of the multiple cell units, and whose source/drain is each connected to the other end of the first bit line and the second bit line.

19. The nonvolatile semiconductor memory device according to claim 17 further comprising:
a bit line charge-discharge transistor on at least one end of the divided bit lines.

20. The nonvolatile semiconductor memory of claim 19, further including a second bit line charge-discharge transistor located between the bit line charge-discharge transistor and an end of the bit line.
